(19) United States
(12) Patent Application Publication
(10) Pub. No.: US 2009/0310320 A1
(43) Pub. Date: Dec. 17, 2009

(54) Low profile solder grid array technology for printed circuit board surface mount components

(76) Inventors: Weston Roth, Portland, OR (US); Kevin Byrd, Lake Oswego, OR (US); Damion Searls, Hillsboro, OR (US); James D. Jackson, Beaverton, OR (US)

Correspondence Address: INTEL CORPORATION;c/o CPA Global, P.O. BOX 52050, MINNEAPOLIS, MN, 55402, US

(21) Appl. No.: 12/214,006

(22) Filed: Jun. 16, 2008

(51) Int. Cl. H05K 7/06; H05K 3/34

(52) U.S. Cl. 361/768; 228/180.1

(57) ABSTRACT

A standoff contact array is disposed between a mounting substrate of a flip-chip package and a board. The standoff contact array is formable by mating a low-profile solder bump on the mounting substrate with a low-profile solder paste on the board. Thereafter, the standoff contact array is formed by reflowing the low-profile solder paste on the board against the low-profile solder bump on the mounting substrate.

### TECHNICAL FIELD

Disclosed embodiments relate to semiconductive apparatus, packages, and processes of making them.

### BRIEF DESCRIPTION OF THE DRAWINGS

In order to understand the manner in which embodiments are obtained, a more particular description of various embodiments briefly described above will be rendered by reference to the appended drawings. These drawings depict embodiments that are not necessarily drawn to scale and are not to be considered to be limiting in scope. Some embodiments will be described and explained with additional specificity and detail through the use of the accompanying drawings in which:

FIG. 1a is a cross-section elevation of a semiconductive integrated circuit package according to an embodiment;

FIG. 1b is a cross-section elevation of a semiconductive integrated circuit package after further processing of the package depicted in FIG. 1a according to an embodiment;

FIG. 1c is a cross-section elevation of a semiconductive integrated circuit package after further processing of the package depicted in FIG. 1b according to an embodiment;

FIG. 1d is a cross-section elevation of a semiconductive integrated circuit package after further processing of the package depicted in FIG. 1c according to an embodiment;

FIG. 1e is a cross-section elevation of a semiconductive integrated circuit package after further processing of the package depicted in FIG. 1d according to an embodiment;

FIG. 1f is a cross-section elevation of a semiconductive integrated circuit package after further processing of the package depicted in FIG. 1e according to an embodiment;

FIG. 2 is a detail of the cross-section elevation depicted in FIG. 1d according to an embodiment;

FIG. 3a is a detail cross-section elevation depicted in FIG. 1f according to an embodiment;

FIG. 3b is a detail cross-section elevation depicted in FIG. 1f after processing as illustrated in FIG. 3a according to an embodiment;

FIG. 4 is a method flow diagram 400 according to an embodiment; and

FIG. 5 is a schematic of an electronic system according to an embodiment.

### DETAILED DESCRIPTION

A low-profile solder grid array is formed on a mounting substrate by allowing a solder paste to reflow into low-profile solder bumps. The low-profile solder grid array is mounted to a board by contacting each low-profile solder bump to a low-profile solder paste on the board. The low-profile solder paste is then reflowed to bond with the low-profile solder bump.

Reference will now be made to the drawings wherein like structures may be provided with like suffix reference designations. In order to show the structures of various embodiments most clearly, the drawings included herein are diagrammatic representations of integrated circuit structures. Thus, the actual appearance of the fabricated structures, for example in a photomicrograph, may appear different while still incorporating the claimed structures of the illustrated embodiments. Moreover, the drawings show only the structures necessary to understand the illustrated embodiments. Additional structures known in the art have not been included to maintain the clarity of the drawings.

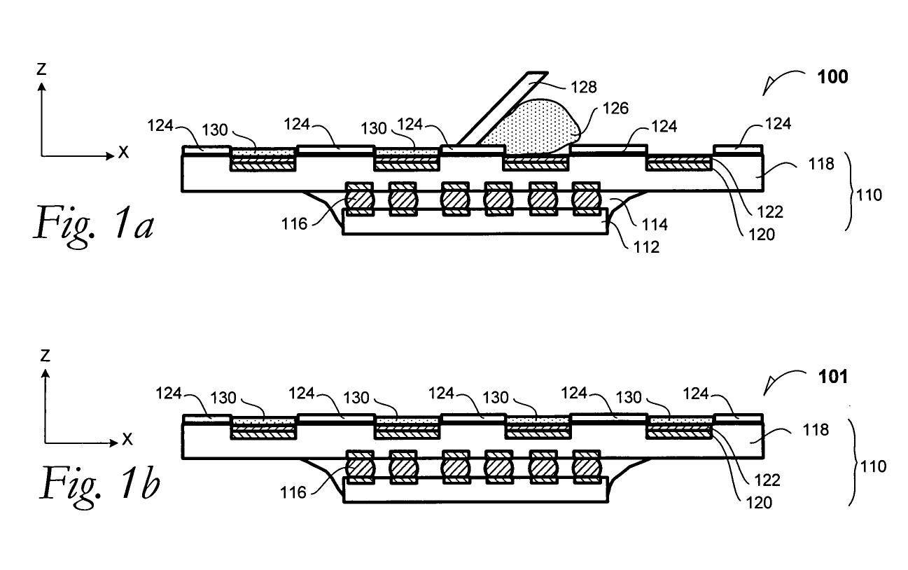

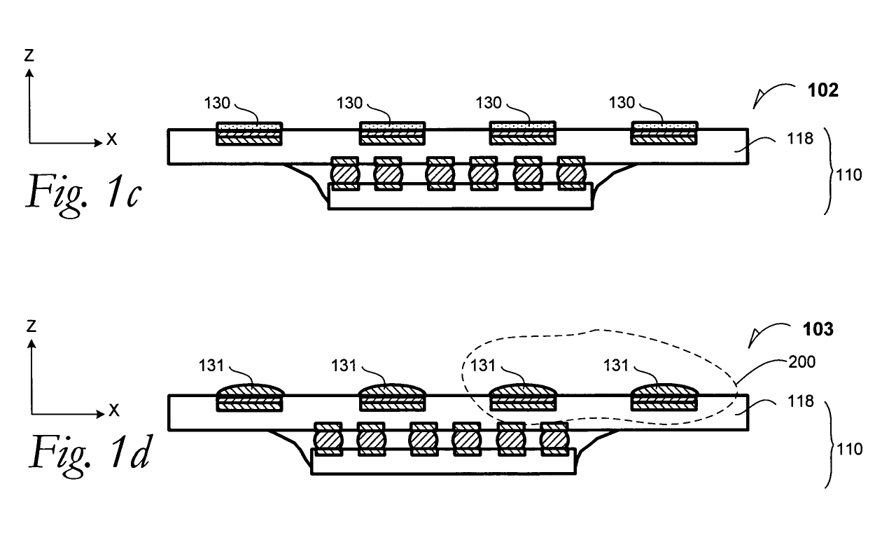

FIG. 1a is a cross-section elevation of a semiconductive integrated circuit package 100 according to an embodiment. A flip-chip package 110 includes a semiconductive integrated circuit 112 (hereinafter “chip”), an underfill material 114, a plurality of solder balls, one of which is indicated by reference numeral 116, and a mounting substrate 118. The chip 112 is electrically connected to the mounting substrate 118 by the plurality of solder balls 116. In an embodiment, the mounting substrate 118 is configured with a plurality of bond pads, one of which is indicated by reference numeral 120. The bond pads 120 may have a surface finish 122 such as a metal that is more noble than the metal of the bond pad 120. For an example embodiment, the bond pads 120 are copper metal and the surface finish 122 is gold metal. In an example embodiment, the bond pads 120 are copper metal and the surface finish 122 is platinum-group metal. In an example embodiment, the bond pads 120 are copper metal and the surface finish 122 is nickel-palladium-gold alloy. During processing, a mask 124 is superimposed over the mounting substrate 118 to expose the bond pads 120. A solder paste 126 is patterned onto the bond pads 120 by use of a squeegee 128 by way of non-limiting example. In any event the solder paste 126 is imposed onto the bond pads 120 to form a solder paste array 130. In an embodiment, the solder paste 126 is derived from lead free metal powders of tin (Sn). In an embodiment, the solder paste 126 is a tin-silver (Sn—Ag) composition. In an embodiment, the solder paste 126 is a tin-silver-copper (Sn—Ag—Cu) composition such as SAC305 (which is Sn96.5/Ag3.0/Cu0.5). In an embodiment, the solder paste 126 is a Sn—Ag—Cu composition such as SAC405 (which is Sn3.8Ag0.7Cu). In an embodiment a tin-antimony (Sn—Sb) solder paste 126 is used. In an embodiment, the spolder patst 126 is an eutectic powder tin-lead (Sn—Pb).

In an embodiment, the solder paste 126 has an average metal particle diameter in a range from about 5 μm to about 45 μm.

FIG. 1b is a cross-section elevation of a semiconductive integrated circuit package 101 after further processing of the package 100 depicted in FIG. 1a according to an embodiment. The solder paste array 130 is depicted has having a flat profile in relation to the mask 124 when it is viewed in the X-Z plane. In an embodiment, the profile of each element in the solder paste array 130 is controlled by the thickness of the mask 124. For example, the mask 124 has a thickness that will leave a solder bump, in solder-paste form, with a height in a range from 100 micrometer (μm) to 200 μm. In an embodiment, the pitch, center-to-center, between two occurrences of the solder paste array 130 on the mounting substrate 118 is 0.6 millimeter (mm) and the height of each occurrence of the solder paste array 130 is in a range from about 170 to 200 μm. In an embodiment, the pitch between two occurrences of the solder paste array 130 mounting substrate 118 is 0.5 mm and the height of each occurrence of the solder paste array 130 is in a range from 50 μm to about 100 μm.

In an embodiment, the structures represented by numeral 130 are electrical connectors such as metal studs. Although the aspect ratio (Z-dimension divided by X-dimension) is less than one, the structures 130 may be called contact studs. In this embodiment, the structure represented by numeral 122 may be a wetting layer for the stud 120. For example, the wetting layer 122 may be a solder paste embodiment and the stud 130 is a copper stud. Hereinafter, the structure 130 will be referred to as a solder paste array 130 unless explicitly taught otherwise.

In an embodiment, individual occurrences in the solder paste array 130 may have varying diameters depending upon location. For example bond pads 120 near the periphery of the mounting substrate 118 may have a first diameter 160 that is larger than bond pads nearer the center thereof that have a second diameter 162. This variation in bond pad size and the corresponding low-profile solder bump may allow for useful stress resistance at the periphery where thermal stresses and physical shocks may be experienced with greater intensity.

FIG. 1c is a cross-section elevation of a semiconductive integrated circuit package 102 after further processing of the package 101 depicted in FIG. 1b according to an embodiment. After forming the solder paste array 130, the mask 124 (FIG. 1b) is removed.

FIG. 1d is a cross-section elevation of a semiconductive integrated circuit package 103 after further processing of the package 102 depicted in FIG. 1c according to an embodiment. The solder paste array 130 (FIG. 1c) has been reflowed to form a low-profile solder bump array 131.

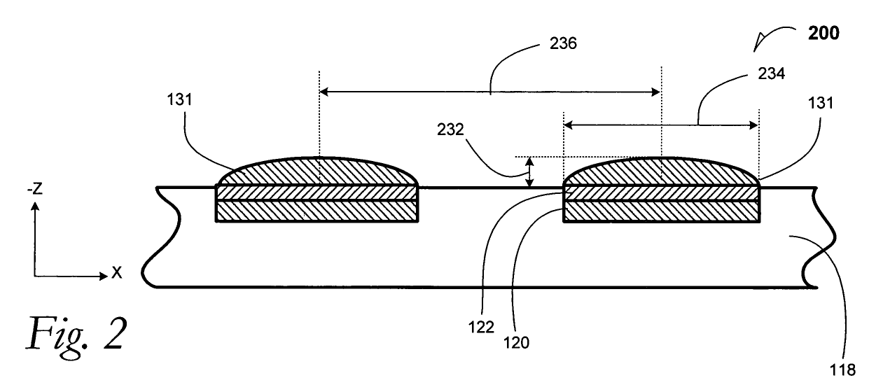

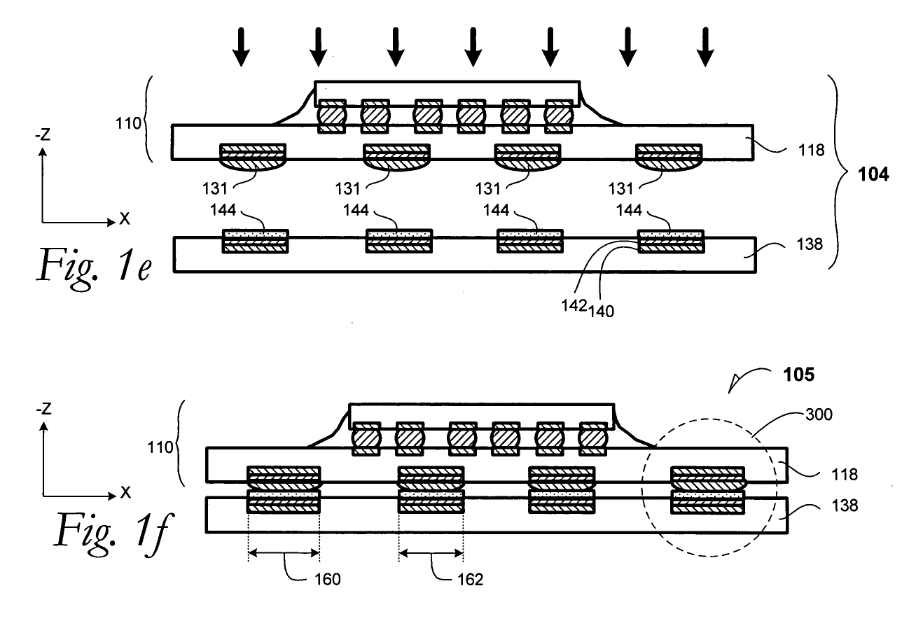

FIG. 2 is a detail 200 of the cross-section elevation depicted in FIG. 1d according to an embodiment. The detail 200 is taken along the section line 200 in FIG. 1d. The mounting substrate 118 is illustrated in detail section with two occurrences of bond pads 120 and corresponding surface finishes 122. Two occurrences from the low-profile solder bump array 131 are also depicted. Each low-profile solder bump 131 has a bump height 232 and a bump width 234. An aspect ratio for each low-profile solder bump 131 is given as bump height 232 divided by bump width 234. Additionally in an embodiment where the width 234 of a bond pad 120 is given as unity, the pitch 236 is given as 1.5 times unity.

In an embodiment, the aspect ratio is based upon the 0.6 mm pitch embodiment, where the pitch is 1.5 times the width 234 of the bond pad 120. Consequently, where each low-profile solder bump 131 has an aspect ratio of 170 μm divided by 0.4 mm, or an aspect ratio of about 0.425. In an embodiment, where each low-profile solder bump 131 has an aspect ratio of 200 μm divided by 0.4 mm, or an aspect ratio of about 0.5. In an embodiment where the bond pad 120 has a diameter of 300 μm and the pitch is 0.6 mm, the aspect ratio with a 200 μm bump standoff is 0.67.

In an embodiment, the aspect ratio is based upon the 0.5 mm pitch embodiment, where the pitch 236 is 1.5 times the width 234 of the bond pad 120. Consequently, where each low-profile solder bump 131 has an aspect ratio of 100 μm divided by 333 mm, or an aspect ratio of about 0.3. In an embodiment where the bond pad 120 has a diameter of 200 μm and the pitch is 0.5 mm, the aspect ratio with a 100 μm bump standoff is 0.5.

Other pitches may be applied to the illustrated embodiments. In an embodiment, the pitch 236 is 1.33 times the width 234 of the bond pad 120. In an embodiment, the pitch 236 is 1.25 times the width 234 of the bond pad 120. In an embodiment, the pitch 236 is equal to the width 234 of the bond pad 120. In an embodiment, the pitch 236 is 1.67 times the width 234 of the bond pad 120. In an embodiment, the pitch 236 is double the width 234 of the bond pad 120.

FIG. 1e is a cross-section elevation of a semiconductive integrated circuit package 104 after further processing of the package 103 depicted in FIG. 1d according to an embodiment. The flip-chip package 110 has been inverted with respect to the Z-axis as illustrated. The flip-chip package 110 is depicted as being mated with a board 138 such as a printed wiring board according to an embodiment. The directional arrows illustrate that the mounting substrate 118 and the board 138 are being brought together. The board 138 is configured with a plurality of bond pads, one of which is indicated by reference numeral 140. Similarly to the bond pads 120 on the mounting substrate 118, the bond pads 140 on the board 138 may have a surface finish 142. Similarly also, the surface finish 142 may be a metal or alloy that is more noble than the metal of the bond pad 140 according to an embodiment.

The board 138 also includes a solder paste array. Four occurrences of a board solder paste array 144 are illustrated. In a process embodiment, the reflowed low-profile solder bump array 131 is being mated to corresponding occurrences of the board solder paste array 144. In a process embodiment, a process of assembling the a solder grid array 131 of the microelectronic device package 110 is demonstrated such that the low-profile solder bumps 131 are being mated to a board solder paste array 144 that is disposed on the printed wiring board substrate 138. The assembly of a plurality of reflowed low-profile solder bumps 131 to a board solder paste array 144 may be accomplished in this illustrated embodiment.

FIG. 1f is a cross-section elevation of a semiconductive integrated circuit package 105 after further processing of the package 104 depicted in FIG. 1f according to an embodiment. The package 105 includes the mounting substrate 118 mated with the board 138 with contact between the low-profile solder bump array 131 and the board solder paste array 144.

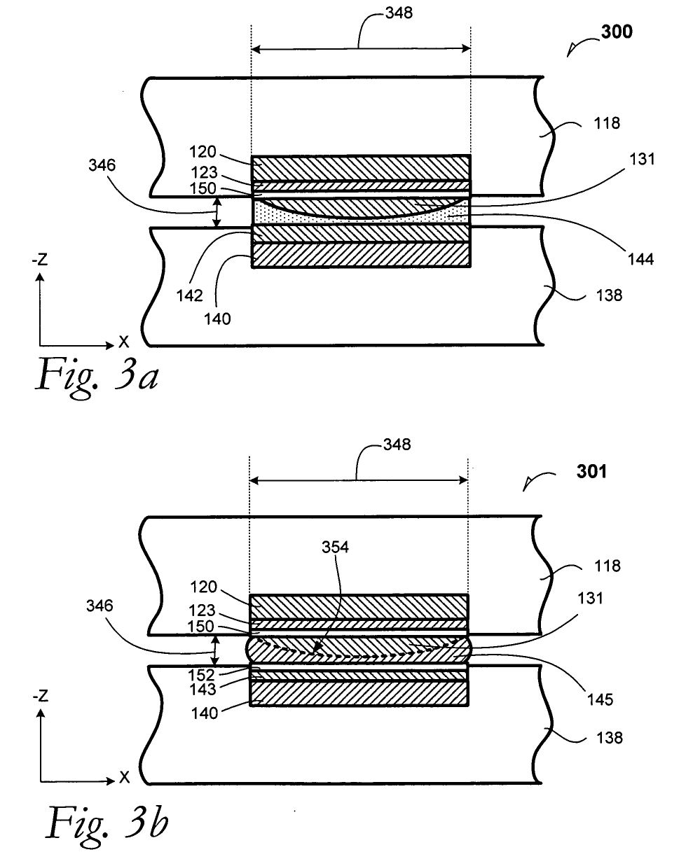

FIG. 3a is a detail 300 of the cross-section elevation depicted in FIG. 1f according to an embodiment. The detail 300 is taken along the section line 300 in FIG. 1f. The mounting substrate 118 is illustrated in detail section with one occurrence of a bond pad 120. Further detail is illustrated in FIG. 3a that may be also found in embodiments described and illustrated in FIG. 2. For example, during reflow of the low-profile solder bump array 131, a portion of the surface finish 122 may be consumed to form a package intermetallic layer 150 and a package residual surface finish 123. The package intermetallic layer 150 is formed from consumed surface finish 122 and a portion of solder from the solder paste.

FIG. 3a also depicts the board solder paste 144 in direct contact with the low-profile solder bump 131. The combined board solder paste 144 and low-profile solder bump 131 exhibit a package bump height 346 and a package bump width 348. The package bump width 348 is defined as the characteristic width 348 or diameter of the bond pads 120 and 140. An aspect ratio for each package bump is given as package bump height 346 divided by package bump width 348.

FIG. 3b is a detail 300 of the cross-section elevation depicted in FIG. 1f after further processing of the structure depicted in FIG. 3a according to an embodiment. The board solder paste 144 (FIG. 3a) has been reflowed into a board bump 145. Reflow has also resulted in at least partial consumption of the surface finish 142 depicted in FIG. 1e to form a residual surface finish 143 and a board intermetallic layer 152.

In an embodiment, the board bump 145 has a chemical composition that is distinct from the low-profile solder bump 131. As a result of reflow of the board solder paste 144, useful wetting contact is made between the board bump 145 and the low-profile solder bump 131 without significant mass transfer.

In an embodiment, the low-profile solder bump 131 has been diluted by incursion of reflowed materials of the board bump 145. As a result of reflow of the board solder paste 144, components of the board solder paste 144 dissolve into the low-profile solder bump 131 based upon solder-phase thermodynamics. Consequently, the solder chemistry of the low-profile solder bump 131 is significantly different from the solder chemistry of the solder paste 130. Similarly, the solder chemistry of the board bump 145 is significantly different from the solder chemistry of the board solder paste 144. And further, the solder chemistry of the low-profile solder bump 131 and the board bump 145 are the same.

In an embodiment, the low-profile solder bump 131 has been only partially infiltrated by reflowed materials of the board bump 145. As a result of reflow of the board solder paste 144, components of the board solder paste 144 dissolve into the low-profile solder bump 131 based upon solder-phase thermodynamics. The degree of dissolution thereof, however, is limited such that the low-profile solder bump 131 near the residual surface finish 123 is significantly unaffected by the materials of the board bump 145. Similarly, the degree of dissolution of the materials of the board bump 145 into the low-profile solder bump 131 is limited such that the board bump 145 has a chemistry similar to the board solder paste 144 near the residual surface finish 143. In this embodiment, a transition zone 354 is illustrated as a dashed line between the low-profile solder bump 131 and the board bump 145. The extent of the transition zone represents a regional dilution of the low-profile solder bump 131 and the board bump 145. The low-profile solder bump 131 and the board bump 145 may be varied based upon specific reflow conditions and solder chemistries of the low-profile solder bump 131 and the board bump 145.

A package-to-bond pad width standoff ratio is defined as the cumulative height 346 of the bumps 131 and 145 divided by the bond pad width 348. This ratio hereinafter is referred to as the standoff ratio.

In an embodiment based upon a 0.6 mm pitch embodiment where the pitch is 1.5 times the width of the bond pad 120, the standoff ratio is about 0.425. In a 0.425 standoff ratio embodiment, the cumulative height is 170 μm. In an embodiment based upon a 0.6 mm pitch embodiment where the pitch is 1.5 times the width of the bond pad 120, the standoff ratio is about 0.5. In a 0.400 standoff ratio embodiment, the cumulative height is 200 μm. In an embodiment based upon a 0.6 mm pitch embodiment where the pitch is 1.5 times the width of the bond pad 120, the standoff ratio is about 0.3.

In an embodiment based upon a 0.5 mm pitch embodiment where the pitch is 1.5 times the width of the bond pad 120, the standoff ratio about 0.3. In a 0.3 standoff ratio embodiment, the cumulative height is 100 μm.

In an embodiment, the standoff ratio is achieved without solder bumps. In an embodiment, the height 346 of the structure is achieved with a conductive stud that is in direct contact to each of the bond pads 120 and 140. In an embodiment, the height 346 is achieved by a conductive stud that is electrically connected by a solder film. In FIG. 3b, the structures 131 and 145 represent an integral stud structure such that the boundary 354 is not present. Further, the structures 150 and 152 represent solder films that bond the conductive stud 131 and 145 to the respective bond pads 120 and 140. In an embodiment, the conductive stud 131 and 145 is copper, the pads 120 and 140 are copper, and the solder films 150 and 152 are derived from solder paste. In an embodiment, FIG. 3b is drawn to scale with respect to the height 346 and the width 348 and the aspect ratio can be ascertained by rational comparison of such height 346, divided by such width 348 as illustrated. Further, this aspect ratio may vary by plus-or-minus 10 percent.

Whether the standoff ratio is achieved with solder pastes or with studs, the electrical structures achieved by these processes may be referred to as standoff contacts.

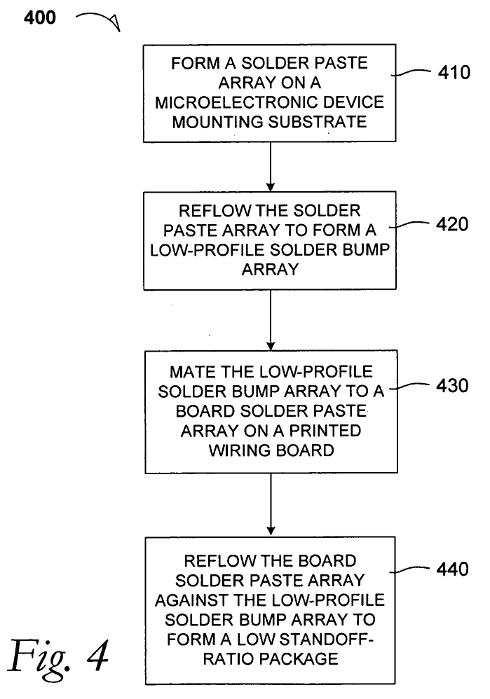

FIG. 4 is a process flow diagram 400 according to an embodiment.

At 410, the process includes forming a solder paste array on a microelectronic device mounting substrate. A non-limiting example is depicted in FIGS. 1a through 1c.

At 420, the process includes reflowing the solder paste array to form a low-profile solder bump. A non-limiting example is depicted in FIG. 1d.

At 430, the process includes mating the low-profile solder bump array to a board solder paste array on a printed wiring board. A non-limiting example is depicted in FIGS. 1e and 1f. In an embodiment, the process commences and terminates at 430. In an embodiment, the process commences at 410 and terminates at 430.

At 440, the process includes reflowing the board solder paste array against the low-profile solder bump array to form a low standoff-ratio package with low-profile standoff contacts. A non-limiting example is depicted at FIG. 3b. In an embodiment, the low-profile standoff contacts are formed by the use of studs.

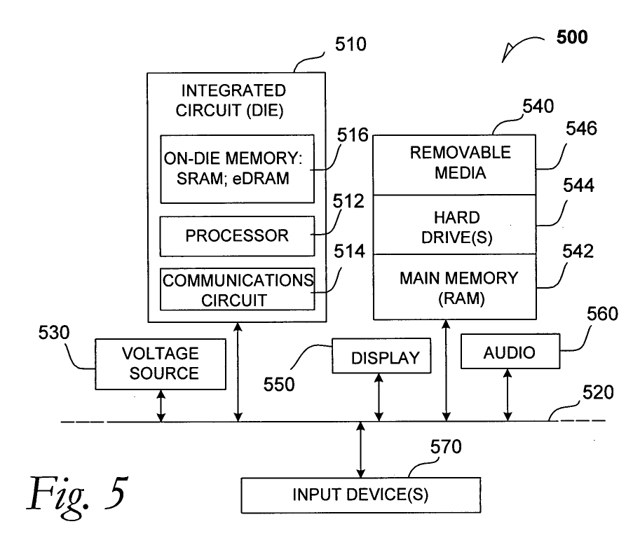

FIG. 5 is a schematic of an electronic system 500 according to an embodiment. The electronic system 500 as depicted can embody an apparatus that exhibits a standoff ratio embodiment as set forth in this disclosure. In an embodiment, the electronic system 500 is a computer system that includes a system bus 520 to electrically couple the various components of the electronic system 500. The system bus 520 is a single bus or any combination of busses according to various embodiments. The electronic system 500 includes a voltage source 530 that provides power to the integrated circuit 510. In some embodiments, the voltage source 530 supplies current to the integrated circuit 510 through the system bus 520.

The integrated circuit 510 is electrically coupled to the system bus 520 and includes any circuit, or combination of circuits according to an embodiment. In an embodiment, the integrated circuit 510 includes a processor 512 that can be of any type. As used herein, the processor 512 may mean any type of circuit such as, but not limited to, a microprocessor, a microcontroller, a graphics processor, a digital signal processor, or another processor. Other types of circuits that can be included in the integrated circuit 510 are a custom circuit or an ASIC, such as a communications circuit 514 for use in wireless devices such as cellular telephones, pagers, portable computers, two-way radios, and similar electronic systems. In an embodiment, the processor 510 includes on-die memory 516 such as SRAM. In an embodiment, the processor 510 includes on-die memory 516 such as eDRAM.

In an embodiment, the electronic system 500 also includes an external memory 840 that in turn may include one or more memory elements suitable to the particular application, such as a main memory 542 in the form of RAM, one or more hard drives 544, and/or one or more drives that handle removable media 546, such as diskettes, compact disks (CDs), digital video disks (DVDs), flash memory keys, and other removable media known in the art.

In an embodiment, the electronic system 500 also includes a display device 550, an audio output 560. In an embodiment, the electronic system 500 includes a controller 570, such as a keyboard, mouse, trackball, game controller, microphone, voice-recognition device, or any other device that inputs information into the electronic system 500.

As shown herein, the integrated circuit 510 can be implemented in a number of different embodiments, including an electronic package, an electronic system, a computer system, one or more methods of fabricating an integrated circuit, and one or more methods of fabricating an electronic assembly that includes the integrated circuit and the low-profile standoff array integrated circuit die package as set forth herein in the various embodiments and their art-recognized equivalents. The elements, materials, geometries, dimensions, and sequence of operations can all be varied to suit particular packaging requirements.

The Abstract is provided to comply with 37 C.F.R. §1.72(b) requiring an abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

What is claimed is:

1. A process comprising:
forming a solder paste array on a flip-chip mounting substrate;
reflowing the solder paste array to form a plurality of solder bumps in a solder-grid array (SGA); and
assembling the SGA of the flip-chip mounting substrate to a board solder paste array disposed on a printed wiring board substrate.

2. The process of claim 1, further including reflowing the board solder paste array against the SGA to achieve a reflowed board SGA.

3. The process of claim 1, further including reflowing the board solder paste array against the SGA to achieve a reflowed board SGA, wherein reflowing the board solder paste array achieves dilution of at least one solder bump of the SGA by material from the a reflowed board SGA.

4. The process of claim 1, further including reflowing the board solder paste array against the SGA, wherein reflowing the board solder paste array achieves regional dilution of at least one solder bump of the SGA by material from the board solder paste array, wherein regional dilution results in a transition zone disposed between undiluted solder in at least one solder bump of the SGA and reflowed solder from at least one undiluted solder in the board solder paste.

5. The process of claim 1, further including reflowing the board solder paste array against the SGA to achieve a reflowed board SGA, wherein the SGA includes a central area of solder bumps of a first diameter and a peripheral area of solder bumps of a second diameter, and wherein the second diameter is greater than the first diameter.

6. The process of claim 1, wherein the SGA is disposed on a mounting substrate bond pad array, wherein the mounting substrate bond pad array includes a first metal and a surface finish second metal, and wherein during reflowing the solder paste array, the second metal and the solder paste form an intermetallic layer.

7. The process of claim 1, wherein the SGA is disposed on a mounting substrate bond pad array, wherein the mounting substrate bond pad array includes a first metal and a surface finish second metal, and wherein during reflowing the solder paste array, the second metal and the solder paste form an intermetallic layer, the process further including:
reflowing the board solder paste array against the SGA to achieve a reflowed board SGA, wherein the board solder paste array is disposed on a board bond pad array that includes a first metal and a surface finish second metal, and wherein during reflowing the board solder paste array, the second metal and the board solder paste form an intermetallic layer.

8. A process comprising:
assembling a contact stud between a microelectronic device mounting substrate and a board, wherein the contact stud has a height in a range from 100 μm to 200 μm, and wherein the mounting substrate and board exhibit a standoff ratio (contact stud height/bond pad width) from 0.3 to 0.5.

9. The process of claim 8, wherein the contact stud is copper and wherein assembling the contact stud includes disposing the contact stud between solder films derived from solder paste; and
reflowing the solder films under conditions to achieve an average metal grain size in a range from about 10 μm to about 100 μm.

10. The process of claim 8, further including reflowing solder films disposed above and below the contact stud, wherein the contact stud is part of a contact-stud array that includes a central area of contact studs of a first diameter and a peripheral area of contact studs of a second diameter, and wherein the second diameter is greater than the first diameter.

11. An apparatus comprising:
a flip-chip package disposed on a mounting substrate;
a board, wherein the mounting substrate includes a standoff contact array disposed on a plurality of bond pads, wherein the standoff contact array is mated to the board, and wherein the board and the mounting substrate are spaced apart by the standoff contact array with a height range from 100 μm to 200 μm and a standoff ratio (standoff contact height/bond pad width) from 0.3 to 0.5.

12. The apparatus of claim 11, wherein the standoff contact array is a solder grid array (SGA).

13. The apparatus of claim 11, wherein the standoff contact array is a solder grid array (SGA), and wherein the SGA includes a solder first bump in contact with the mounting substrate and a solder second bump in contact with the board.

14. The apparatus of claim 11, wherein the standoff contact array is a copper stud array mated to respective bond pads on the mounting substrate and to respective bond pads on the board.

15. The apparatus of claim 11, wherein the standoff contact array includes a central area of standoff contacts of a first diameter and a peripheral area of standoff contacts of a second diameter, and wherein the second diameter is greater than the first diameter.

16. The apparatus of claim 11, wherein the standoff contact array is a solder grid array (SGA), and wherein the SGA includes a solder first bump in contact with the mounting substrate and a solder second bump in contact with the board, wherein the standoff contact array includes a central area of standoff contacts of a first diameter and a peripheral area of standoff contacts of a second diameter, and wherein the second diameter is greater than the first diameter.

17. The apparatus of claim 11, wherein the standoff contact array is a copper stud array mated to respective bond pads on the mounting substrate and to respective bond pads on the board, wherein the standoff contact array includes a central area of standoff contacts of a first diameter and a peripheral area of standoff contacts of a second diameter, and wherein the second diameter is greater than the first diameter.

18. The apparatus of claim 11, wherein the SGA is disposed on a mounting substrate bond pad array, wherein the mounting substrate bond pad array includes a first metal and a surface finish second metal, and further including an intermetallic layer disposed between the surface finish second metal and the standoff contact array.

19. The apparatus of claim 11, wherein the SGA is disposed on a mounting substrate bond pad array, wherein the mounting substrate bond pad array includes a first metal and a surface finish second metal, further including an intermetallic layer disposed between the surface finish second metal and the standoff contact array, the apparatus further including:
a reflowed board SGA, wherein the board SGA is disposed on a board bond pad array that includes a first metal and a board surface finish second metal; and
an intermetallic layer disposed between the board SGA and the board surface finish.

20. A computing system comprising:
a microelectronic die disposed in a flip-chip package that is disposed on a mounting substrate that includes a plurality of mounting substrate bond pads;
a board, wherein the mounting substrate includes a standoff contact array disposed on the plurality of mounting substrate bond pads, wherein the standoff contact array is mated to the board on a corresponding plurality of board bond pads, and wherein the board and the mounting substrate are spaced apart by the standoff contact array with a height range from 100 μm to 200 μm and a standoff ratio (standoff contact height/bond pad width) from 0.3 to 0.5; and
external memory coupled to the microelectronic die.

21. The computing system of claim 20, wherein the standoff contact array includes a reflowed mounting substrate solder grid array and a reflowed board solder grid array.

22. The computing system of claim 20, wherein the standoff contact array includes a contact stud array.
